(19) United States
(12) Patent Application Publication
(10) Pub. No.: US 2019/0347044 A1
(43) Pub. Date: Nov. 14, 2019

(54) CONTROLLER, MEMORY SYSTEM AND OPERATING METHOD THEREOF

(71) Applicant: SK hynix Inc., Gyeonggi-do (KR)

(72) Inventor: Young-Gyun KIM, Seoul (KR)

(21) Appl. No.: 16/208,939

(22) Filed: Dec. 4, 2018

(30) Foreign Application Priority Data
May 8, 2018 (KR) 10-2018-0052255

(51) Int. Cl. G06F 3/06; G11C 16/28; G11C 16/32; G11C 7/10

(52) U.S. Cl. CPC G06F 3/0659; G06F 3/0649; G06F 3/0614; G11C 7/1048; G11C 16/28; G11C 16/32; G06F 3/0679

(57) ABSTRACT

A controller that controls a memory device includes a temporary storage suitable for storing a request provided from a host, a command generator suitable for generating any one of a first command and a second command corresponding to the request based on an attribute of data corresponding to the request, and a command controller suitable for providing the generated command to the memory device.

### CROSS-REFERENCE TO RELATED APPLICATION(S)

The present application claims priority under 35 U.S.C. § 119(a) to Korean Patent Application No. 10-2018-0052255, filed on May 8, 2018, the entire disclosure of which is incorporated herein by reference in its entirety.

### BACKGROUND

### 1. Field

Various embodiments of the present invention generally relate to an electronic device. Particularly, the embodiments relate to a controller capable of controlling a memory system and a nonvolatile memory device and an operating method of the controller.

### 2. Description of the Related Art

The computer environment paradigm has been shifting to ubiquitous computing, which enables computer systems to be used anytime and anywhere. As a result, use of portable electronic devices such as mobile phones, digital cameras, and notebook/laptop computers has rapidly increased. These portable electronic devices generally use a memory system having one or more memory devices for storing data. A memory system in such device may be used as a main memory device or an auxiliary memory device.

Such memory systems provide excellent stability, durability, high information access speed, and low power consumption since they have no moving parts. Examples of memory systems having such advantages include universal serial bus (USB) memory devices, memory cards having various interfaces, and solid state drives (SSD).

### SUMMARY

Various embodiments of the present invention are directed to a memory system capable of performing an optimized operation, a controller capable of controlling the memory system and an operating method of the controller.

In accordance with an embodiment of the present invention, a controller that controls a memory device includes: a temporary storage suitable for storing a request provided from a host; a command generator suitable for generating any one of a first command and a second command corresponding to the request based on an attribute of data corresponding to the request; and a command controller suitable for providing the generated command to the memory device.

In accordance with an embodiment of the present invention, an operating method of a memory system includes: storing a request provided from a host; generating any one of a first command and a second command corresponding to the request based on an attribute of data corresponding to the request; providing the generated command to a memory device; and performing, by the memory device, an operation corresponding to the command.

In accordance with an embodiment of the present invention, a memory system includes: a controller including a temporary storage suitable for storing a request provided from a host, a command generator suitable for generating any one of a first command and a second command corresponding to the request based on an attribute of data corresponding to the request, a command controller suitable for providing the generated command to the memory device; and a memory device suitable for performing an operation corresponding to the command.

In accordance with an embodiment of the present invention, a memory system includes: a memory device; and a controller suitable for providing the memory device with a command together with corresponding data, wherein the memory device performs, in response to a program command, a program operation for initial and intermediate data of sequential data without application of a dummy pulse to a word line.

In accordance with an embodiment of the present invention, a memory system includes: a memory device; and a controller suitable for providing the memory device with a command together with corresponding data, wherein the memory device performs, in response to a read operation, a one-shot read operation for sequential data, and performs a partial page read operation for random data.

In accordance with an embodiment of the present invention, a memory system includes: a memory device; and a controller suitable for providing the memory device with a command together with corresponding data, wherein the memory device performs, in response to a program operation, a program operation for cold data with a first initial program voltage and a first step voltage and for hot data with a second initial program voltage and a second step voltage, and wherein the second initial program voltage and the second step voltage are respectively greater than the first initial program voltage and the first step voltage.

In accordance with an embodiment of the present invention, a memory system includes: a memory device; and a controller suitable for providing the memory device with a command together with corresponding data, wherein the memory device performs, in response to a read operation, a read operation for cold data with first read and pass voltages and for hot data with second read and pass voltages, and wherein the second read and pass voltages are respectively lower than the first read and pass voltages.

In accordance with an embodiment of the present invention, a memory system includes: a memory device; and a controller suitable for providing the memory device with a command together with corresponding data, wherein the memory device performs, in response to a read operation, a read operation for cold data with first precharge and sensing time and for hot data with second precharge and sensing time, and wherein the second precharge and sensing time are respectively shorter than the first precharge and sensing time.

### BRIEF DESCRIPTION OF THE DRAWINGS

FIG. 1 is a block diagram illustrating a data processing system in accordance with an embodiment of the present invention.

FIG. 2 is a schematic diagram illustrating an exemplary configuration of a memory device employed in a memory system of FIG.

FIG. 3 is a circuit diagram illustrating an exemplary configuration of a memory cell array of a memory block in a memory device shown in FIG. 1.

FIG. 4 is a schematic diagram illustrating an exemplary three-dimensional (3D) structure of the memory device of FIG. 2.

FIG. 5 is a schematic diagram illustrating a structure of a controller in accordance with an embodiment of the present invention.

FIG. 6 is a flowchart describing an operation of a controller in accordance with an embodiment of the present invention.

FIGS. 7 to 10B are flowcharts describing an operation of a memory device.

FIGS. 11 to 19 are diagrams schematically illustrating application examples of the data processing system in accordance with various embodiments of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention. It is noted that reference to “an embodiment” does not necessarily mean only one embodiment, and different references to “an embodiment” are not necessarily to the same embodiment(s).

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments. When an element is referred to as being connected or coupled to another element, it should be understood that the former can be directly connected or coupled to the latter, or electrically connected or coupled to the latter via an intervening element therebetween.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well and vice versa, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

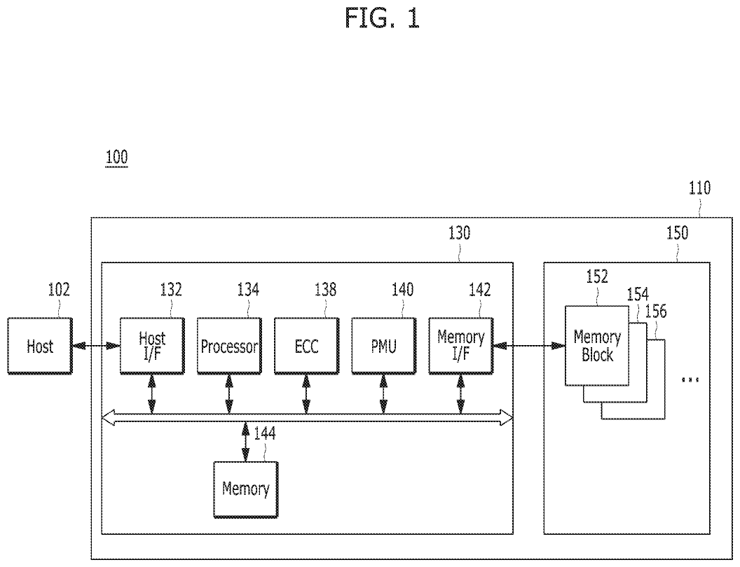

FIG. 1 is a block diagram illustrating a data processing system 100 in accordance with an embodiment of the present invention.

Referring to FIG. 1, the data processing system 100 may include a host 102 operatively coupled to a memory system 110.

The host 102 may include any one of various portable electronic devices such as a mobile phone, MP3 player and laptop computer, or any of various non-portable electronic devices such as a desktop computer, game machine, TV, and projector.

The host 102 may include at least one operating system (OS), which may manage and control overall functions and operations of the host 102, and provide operation between the host 102 and a user using the data processing system 100 or the memory system 110. The OS may support functions and operations corresponding to the use purpose and usage of a user. For example, the OS may be divided into a general OS and a mobile OS, depending on the mobility of the host 102. The general OS may be divided into a personal OS and an enterprise OS, depending on the environment of a user. For example, the personal OS configured to support a function of providing a service to general users may include Windows and Chrome, and the enterprise OS configured to secure and support high performance may include Windows server, Linux and Unix. Furthermore, the mobile OS configured to support a function of providing a mobile service to users and a power saving function of a system may include Android, iOS and Windows Mobile. The host 102 may include a plurality of OSs, and execute an OS to perform an operation corresponding to a user's request on the memory system 110.

The memory system 110 may operate to store data for the host 102 in response to a request of the host 102. Non-limiting examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC, and the. The SD card may include a mini-SD card and micro-SD card.

The memory system 110 may be embodied by various types of storage devices. Examples of such storage devices may include, but are not limited to, volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM) and a flash memory. The flash memory may have a 3-dimensional (3D) stack structure.

The memory system 110 may include a memory device 150 and a controller 130. The memory device 150 may store data for the host 102, and the controller 130 may control data storage into the memory device 150.

The controller 130 and the memory device 150 may be integrated into a single semiconductor device, which may be included in the various types of memory systems as exemplified above. For example, the controller 130 and the memory device 150 may be integrated as one semiconductor device to constitute an SSD. When the memory system 110 is used as an SSD, the operating speed of the host 102 connected to the memory system 110 may be improved. In addition, the controller 130 and the memory device 150 may be integrated as one semiconductor device to constitute a memory card. By way of example and not limitation, the controller 130 and the memory device 150 may constitute a memory card such as a PCMCIA (personal computer memory card international association) card, CF card, SMC (smart media card), memory stick, MMC including RS-MMC and micro-MMC, SD card including mini-SD, micro-SD and SDHC, or UFS device.

Non-limiting application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory blocks 152, 154, 156 . . . (hereinafter, referred to as “memory blocks 152 to 156”) each of which may include a plurality of pages, and each of the pages may include a plurality of memory cells coupled to a word line. In an embodiment, the memory device 150 may be a flash memory. The flash memory may have a 3-dimensional (3D) stack structure.

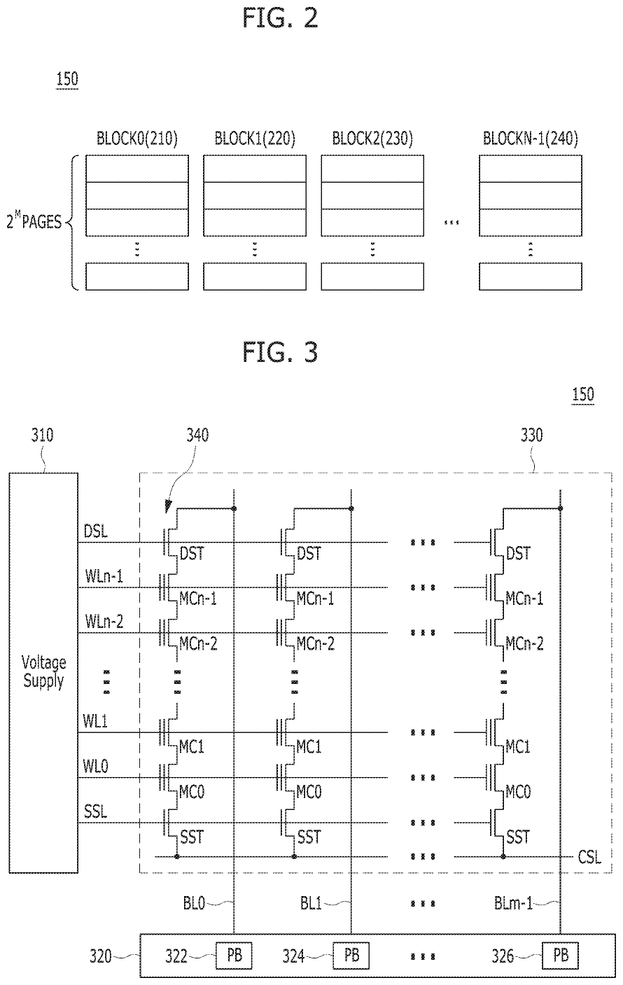

Since the structure of the memory device 150 including its 3D stack structure will be described in detail later with reference to FIGS. 2 to 4, further description of these elements and features are omitted herein.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program and erase operations of the memory device 150.

The controller 130 may include a host interface (I/F) 132, a processor 134, an error correction code (ECC) component 138, a Power Management Unit (PMU) 140, a memory I/F 142 such as a NAND flash controller (NFC), and a memory 144 all operatively coupled via an internal bus.

The host interface 132 may be configured to process a command and data of the host 102, and may communicate with the host 102 through one or more of various interface protocols such as universal serial bus (USB), multi-media card (MMC), peripheral component interconnect-express (PCI-e or PCIe), small computer system interface (SCSI), serial-attached SCSI (SAS), serial advanced technology attachment (SATA), parallel advanced technology attachment (PATA), enhanced small disk interface (ESDI) and integrated drive electronics (IDE).

The ECC component 138 may detect and correct an error contained in the data read from the memory device 150. In other words, the ECC component 138 may perform an error correction decoding process to the data read from the memory device 150 through an ECC code used during an ECC encoding process. According to a result of the error correction decoding process, the ECC component 138 may output a signal, for example, an error correction success/fail signal. When the number of error bits is more than a threshold value of correctable error bits, the ECC component 138 may not correct the error bits, and may output an error correction fail signal.

The ECC component 138 may perform error correction through a coded modulation such as Low Density Parity Check (LDDC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC component 138 is not limited to any specific structure. The ECC component 138 may include all circuits, modules, systems or devices for error correction.

The PMU 140 may provide and manage power of the controller 130.

The memory I/F 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the memory I/F 142 may generate a control signal for the memory device 150 and process data to be provided to the memory device 150 under the control of the processor 134. The memory I/F 142 may work as an interface (e.g., a NAND flash interface) for processing a command and data between the controller 130 and the memory device 150. Specifically, the memory I/F 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

The processor 134 may control the overall operations of the memory system 110. The processor 134 may drive firmware to control the overall operations of the memory system 110. The firmware may be referred to as flash translation layer (FTL). Also, the processor 134 may be realized as a microprocessor or a Central Processing Unit (CPU).

For example, the controller 130 may perform an operation requested by the host 102 in the memory device 150 through the processor 134, which is realized as a microprocessor or a CPU. In other words, the controller 130 may perform a command operation corresponding to a command received from the host 102, or other source. The controller 130 may perform a foreground operation as the command operation corresponding to the command received from the host 102. For example, the controller 130 may perform a program operation corresponding to a write command, a read operation corresponding to a read command, an erase operation corresponding to an erase command, and a parameter set operation corresponding to a set parameter command or a set feature command.

Also, the controller 130 may perform a background operation onto the memory device 150 through the processor 134, which is realized as a microprocessor or a CPU. The background operation performed onto the memory device 150 may include an operation of copying and processing data stored in some memory blocks among the memory blocks 152 to 156 of the memory device 150 into other memory blocks, e.g., a garbage collection (GC) operation, an operation of swapping between the memory blocks 152 to 156 or between the data of the memory blocks 152 to 156, e.g., a wear-leveling (WL) operation, an operation of storing the map data stored in the controller 130 in the memory blocks 152 to 156, e.g., a map flush operation, or an operation of managing bad blocks of the memory device 150, e.g., a bad block management operation of detecting and processing bad blocks among the memory blocks 152 to 156.

A memory device of the memory system in accordance with an embodiment of the present invention is described in detail with reference to FIGS. 2 to 4.

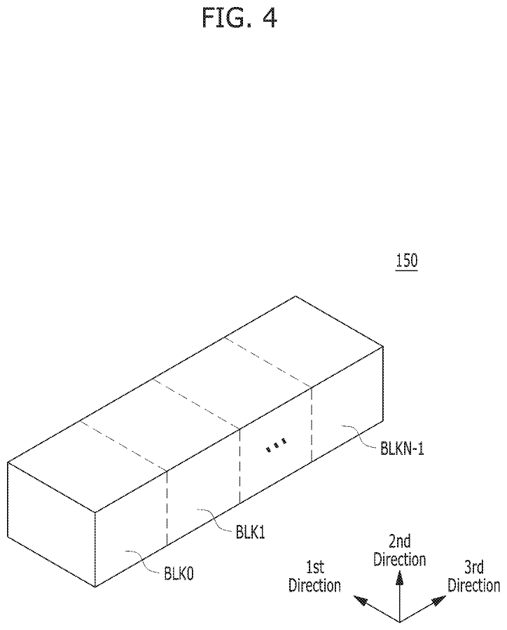

FIG. 2 is a schematic diagram illustrating the memory device 150, FIG. 3 is a circuit diagram illustrating an exemplary configuration of a memory cell array of a memory block in the memory device 150, and FIG. 4 is a schematic diagram illustrating an exemplary 3D structure of the memory device 150.

Referring to FIG. 2, the memory device 150 may include a plurality of memory blocks 0 to N-1, e.g., a memory block 0 BLOCK0 (210), a memory block 1 BLOCKI (220), a memory block 2 BLOCK2 (230) to a memory block N-1 BLOCKN-1 (240). Each of the memory blocks 210, 220, 230 to 240 may include a plurality of pages, for example 2^{M} pages, the number of which may vary according to circuit design. For example, in some applications, each of the memory blocks may include M pages. Each of the pages may include a plurality of memory cells that are coupled to a plurality of word lines WL.

Also, the memory device 150 may include a plurality of memory blocks, which may include a single level cell (SLC) memory block storing 1-bit data and/or a multi-level cell (MLC) memory block storing 2-bit data. The SLC memory blocks may include a plurality of pages that are realized by memory cells storing one-bit data in one memory cell. The SLC memory blocks may have a quick data operation performance and high durability. On the other hand, the MLC memory blocks may include a plurality of pages that are realized by memory cells storing multi-bit data, e.g, data of two or more bits, in one memory cell. The MLC memory blocks may have a greater data storing space than the SLC memory blocks. In other words, the MLC memory blocks may be highly integrated. Particularly, the memory device 150 may include not only the MLC memory blocks, each of which includes a plurality of pages that are realized by memory cells capable of storing two-bit data in one memory cell, but also triple level cell (TLC) memory blocks each of which includes a plurality of pages that are realized by memory cells capable of storing three-bit data in one memory cell, quadruple level cell (QLC) memory blocks each of which includes a plurality of pages that are realized by memory cells capable of storing four-bit data in one memory cell, and/or multiple level cell memory blocks each of which includes a plurality of pages that are realized by memory cells capable of storing five or more-bit data in one memory cell, and so forth.

In accordance with an embodiment of the present invention, the memory device 150 is described as a non-volatile memory, such as a flash memory, e.g., a NAND flash memory. By way of example and not limitation, the memory device 150 may also be realized as any of a Phase Change Random Access Memory (PCRAM), a Resistive Random Access Memory (RRAM or ReRAM), a Ferroelectric Random Access Memory (FRAM), a Spin Transfer Torque Magnetic Random Access Memory (STT-RAM or STT-MRAM).

The memory blocks 210, 220, 230 to 240 may store the data transferred from the host 102 through a program operation, and transfer data stored therein to the host 102 through a read operation.

Referring to FIG. 3, a memory block 330 of the memory device 150 may correspond to any of the plurality of memory blocks 152 to 156 included in the memory device 150 of the memory system 110 may include a plurality of cell strings 340 coupled to a plurality of corresponding bit lines BL0 to BLm-1. The cell string 340 of each column may include one or more drain select transistors DST and one or more source select transistors SST. Between the drain and select transistors DST and SST, a plurality of memory cells MC0 to MCn-1 may be coupled in series. In an embodiment, each of the memory cell transistors MC0 to MCn-1 may be embodied by an MLC capable of storing data information of a plurality of bits. Each of the cell strings 340 may be electrically coupled to a corresponding bit line among the plurality of bit lines BL0 to BLm-1. For example, as illustrated in FIG. 3, the first cell string is coupled to the first bit line BL0, and the last cell string is coupled to the last bit line BLm-1.

Although FIG. 3 illustrates NAND flash memory cells, the invention is not limited in this way. It is noted that the memory cells may be NOR flash memory cells, or hybrid flash memory cells including two or more types of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply 310 which provides word line voltages including a program voltage, a read voltage and a pass voltage to supply to the word lines according to an operation mode. The voltage generation operation of the voltage supply 310 may be controlled by a control circuit (not illustrated). Under the control of the control circuit, the voltage supply 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

The memory device 150 may be embodied by a 2D or 3D memory device. Particularly, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1. FIG. 4 is a block diagram illustrating the memory blocks 152 to 156 of the memory device 150 shown in FIG. 1. Each of the memory blocks 152 to 156 may be realized in a 3D structure (or vertical structure). For example, the memory blocks 152 to 156 may be a three-dimensional structure with dimensions extending in first to third directions, e.g., an x-axis direction, a y-axis direction, and a z-axis direction.

Each memory block 330 included in the memory device 150 may include a plurality of NAND strings NS that are extended in the second direction, and a plurality of NAND strings NS that are extended in the first direction and the third direction. Each of the NAND strings NS may be coupled to a bit line BL, at least one string selection line SSL, at least one ground selection line GSL, a plurality of word lines WL, at least one dummy word line DWL, and a common source line CSL, and each of the NAND strings NS may include a plurality of transistor structures TS.

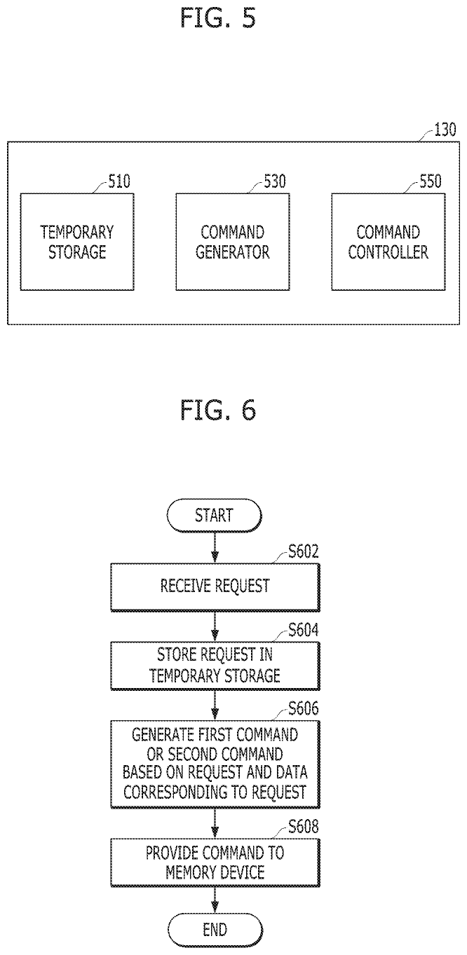

In short, each memory block 330 among the memory blocks 152 to 156 of the memory device 150 may be coupled to a plurality of bit lines BL, a plurality of string selection lines SSL, a plurality of ground selection lines GSL, a plurality of word lines WL, a plurality of dummy word lines DWL, and a plurality of common source lines CSL, and each memory block 330 may include a plurality of NAND strings NS. Also, in each memory block 330, one bit line BL may be coupled to a plurality of NAND strings NS to realize a plurality of transistors in one NAND string NS. Also, a string selection transistor SST of each NAND string NS may be coupled to a corresponding bit line BL, and a ground selection transistor GST of each NAND string NS may be coupled to a common source line CSL. Memory cells MC may be provided between the string selection transistor SST and the ground selection transistor GST of each NAND string NS. In other words, a plurality of memory cells may be realized in each memory block 330 of the memory blocks 152 to 156 of the memory device 150. A data processing operation toward a memory device, particularly, a data processing operation performed when a plurality of command operations corresponding to a plurality of commands are performed, in a memory system in accordance with an embodiment of the present invention is described in detail with reference to FIGS. 5 to 8.

FIG. 5 is a schematic diagram illustrating a structure of the controller 130 in accordance with an embodiment of the present invention.

The memory system 110 may perform an operation in response to a request received from the host 102.

Although there are conventional methods of improving reliability or performance of the operation of a memory system, there may be a trade-off between the improving of the reliability and the improving of the performance.

In accordance with an embodiment of the present invention, the controller 130 may provide a command appropriate to an attribute of data corresponding to the request as well as a type of the request so that the memory device 150 performs an optimized operation for the attribute of the data. Accordingly, overall performance and reliability of the memory system 110 may be improved.

In accordance with an embodiment of the present invention, when the data is cold data, the controller 130 may provide a write command to store data in the memory device 150 with improved reliability because the cold data has to stay stored in the memory device 150 for a long duration. On the other hand, when the data is hot data, the controller 130 may provide a write command to store data in the memory device 150 with improved performance because the hot data has to be accessed rapidly. Consequently, the overall performance and reliability of the memory system 110 may be improved.

Referring to FIG. 5, the controller 130 in accordance with an embodiment of the present invention may include a temporary storage 510, a command generator 530, and a command controller 550.

The temporary storage 510 may temporarily store a request provided from the host 102. The temporary storage 510 may correspond to the memory 144 described above with reference to FIG. 1.

The command generator 530 may generate a command corresponding to the request based on an attribute of data corresponding to the request. The command generator 530 may correspond to the processor 134 described above with reference to FIG. 1.

The command controller 550 may provide the command to the memory device 150. The command controller 550 may correspond to the memory interface 142 described above with reference to FIG. 1.

FIG. 6 is a flowchart describing an operation of the controller 130 in accordance with an embodiment of the present invention.

In step S602, the host interface 132 may receive a request from the host 102.

In step S604, the temporary storage 510 may store the request.

In step S606, the command generator 530 may generate a first command or a second command based on the request stored in the temporary storage 510 and an attribute of the corresponding data.

The request may be any one of a read request and a write request. The data corresponding to the request may be sequential data or random data. The data corresponding to the request may be hot data or cold data. For example, when the request is the write request, the command generator 530 may generate the first command or the second command based on whether the corresponding data is the cold data or the hot data.

In step S608, the command controller 550 may provide the command, which is generated from the command generator 530, to the memory device 150. The memory device 150 may perform a sub-operation, which is determined in advance, based on the provided command.

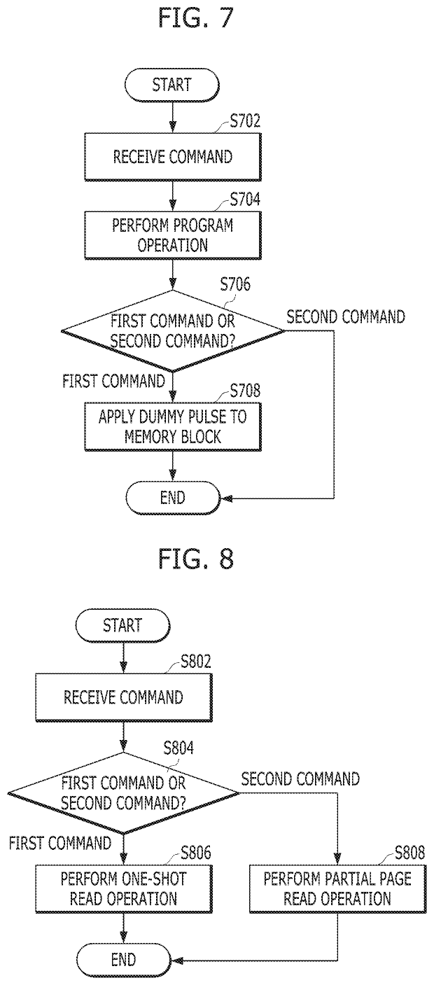

FIGS. 7 to 10B are flowcharts describing an operation of the memory device 150.

FIG. 7 is a flowchart schematically describing a program operation that the memory device 150 performs in response to a write request in accordance with an embodiment of the present invention.

In step S702, the memory device 150 may receive the first command or the second command from the command controller 550 based on an attribute of data corresponding to the write request. Specifically, the memory device 150 may receive the first command together with random data or last data of sequential data. The memory device 150 may receive the second command together with initial or intermediate data of the sequential data.

Specifically, when the controller 130 receives a request together with corresponding data from the host 102, the controller 130 may translate a logical address to a physical address of the data. The controller 130 may determine whether the data is sequential data or random data based on the physical address. And, the controller 130 may determine whether the data is initial, intermediate, or last data of sequential data. The controller 130 may transmit the first command together with random data or last data of sequential data. And the controller 130 may transmit the second command together with initial or intermediate data of the sequential data.

In step S704, the memory device 150 performs the program operation in response to the command provided from the command controller 550.

In step S706, the memory device 150 determines whether the command provided from the command controller 550 in step S702 is the first command or the second command.

When the command is the first command as a result of the determination of the step S706, a subsequent operation is likely to be the read operation because the currently programmed data in response to the first command is the random data or the last data of the sequential data.

During the program operation, it is necessary to apply the dummy pulse in order to prevent an error of the read operation. When a read operation is performed after the program operation is completed, a threshold voltage of a memory cell may be abnormally sensed, resulting in occurrence of an error. According to a prior art, in order to prevent the error, a dummy pulse is applied to the drain selection line DSL and word lines WL0 to WLn-1 of the memory block 330 after the program operation is completed. Since the dummy pulse is unconditionally applied whenever the program operation is completed according to the prior art, a long program time is required.

In step S708, when the command is the first command as a result of the determination of the step S706, the memory device 150 according to an embodiment of the present invention applies the dummy pulse to the drain selection line DSL and word lines WL0 to WLn-1 of the memory block 330, and completes the program operation.

When the command is the second command as the result of the determination of the step S706, the subsequent operation is likely to be the program operation for subsequent data of the sequential data rather than the read operation because the currently programmed sequential data is not the last data of the sequential data. Accordingly, since it is not necessary to prevent the error of the read operation described above even after the current program operation is completed, the memory device 150 completes the program operation without performing step S708.

FIG. 8 is a flowchart schematically describing a read operation that the memory device 150 performs in response to a read request in accordance with an embodiment of the present invention.

In step S802, the memory device 150 may receive the first command together with sequential data from the command controller 550 and receive the second command together with random data from the command controller 550.

In step S804, the memory device 150 may determine whether the command provided from the command controller 550 is the first command or the second command.

When the command is the first command as a result of the determination in step S804, the memory device 150 may perform a one-shot read operation in step S806, and complete the operation.

When the command is the second command as the result of the determination in step S804, the memory device 150 may perform a partial page read operation in step S808, and complete the operation.

During the one-shot read operation, a sensing operation and a data output operation are simultaneously performed on one or more logical pages corresponding a selected word line in a multi-level cell (MLC) memory device 150.

Since the sensing operation and the data output operation are simultaneously performed during the one-shot read operation, a time of the read operation is shortened as compared with a normal read operation during which the logical pages are sequentially read. Since the sequential data of consecutive logical addresses are read during the one-shot read operation, the time required to read data may be shortened.

During the partial page read operation, the sensing operation is performed on some among memory cells coupled to a selected page and the data output operation is performed after the sensing operation is completed. The partial page read operation may include a half page read operation of selecting and reading half of the page at a time and a quarter page read operation of selecting and reading a quarter of the page at a time.

During the partial page read operation, noise of a common source line CSL becomes smaller and a sensing time decreases because the read operation is performed on a part of bit lines coupled to the selected page. For example, only a single fine sensing operation may be performed instead of double coarse-fine sensing operations. Accordingly, the time required to read small data such as 4K random data may be shortened due to the partial page read operation.

According to a prior art, any one of the one-shot read operation and the partial page read operation is unconditionally performed regardless of an attribute of data. However, in accordance with an embodiment of the present invention, when the read operation is performed on the sequential data, the one-shot read operation is performed, and when the read operation is performed on the random data, the partial page read operation is performed, further shortening the time of the read operation.

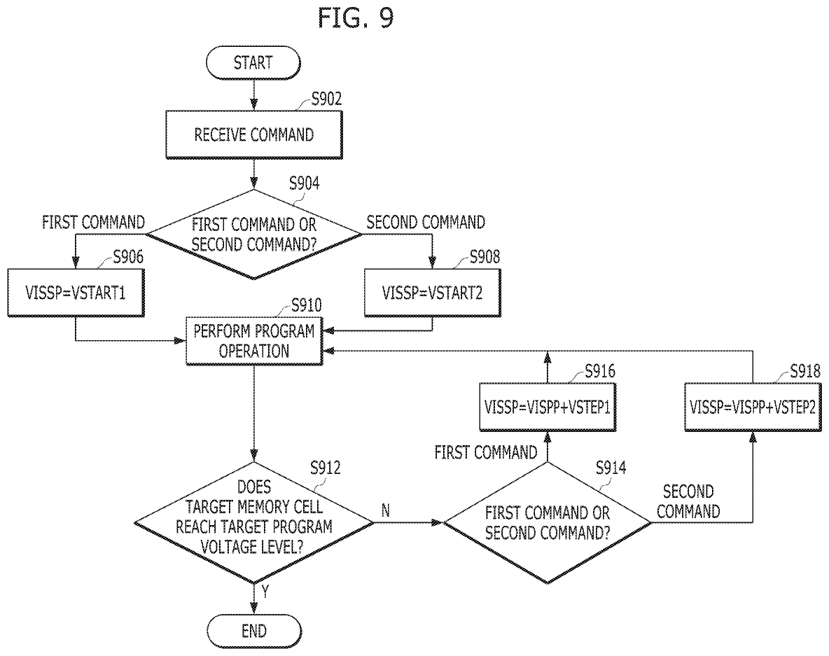

FIG. 9 is a flowchart schematically describing a program operation that the memory device 150 performs in response to a write request in accordance with an embodiment of the present invention.

In step S902, the memory device 150 may receive the first command together with cold data from the command controller 550 and receive the second command together with hot data from the command controller 550.

A program operation based on an incremental step pulse programming (ISPP) scheme is an operation of repeatedly carrying out, until the program operation is passed, a series of processes of applying a pulse of an initial program voltage to perform the program operation, performing a verification operation to determine whether a threshold voltage of a target memory cell reaches a target program voltage level, and increasing a program voltage by a step voltage in a stepwise manner to perform the program operation again when it is determined the threshold voltage of the target memory cell does not reach the target program voltage level.

When the initial program voltage or the step voltage becomes high, a program time is reduced since repetition of the application of the program voltage becomes reduced. However, in this case, charge retention of a floating gate of a memory cell may be reduced and reliability of data may also be reduced. On the contrary, when the initial program voltage or the step voltage becomes lowered, charge retention of a floating gate of a memory cell may increase and the reliability of data may increase although the program time increases since repetition of the application of the program voltage becomes greater. According to a prior art, there is a problem in that either the program time or the reliability has to be sacrificed irrespective of an attribute of the data.

Referring to FIG. 9, in step S904, the memory device 150 according to an embodiment of the present invention determines whether the command provided from the command controller 550 is the first command or the second command.

When the command is the first command as a result of the determination in step S904, the memory device 150 sets a program voltage as a first initial program voltage in step S906, and proceeds to step S910.

When the command is the second command as the result of the determination in step S904, the memory device 150 sets the program voltage as a second initial program voltage in step S908, and proceeds to step S910.

In some embodiments of the present invention, the second initial program voltage may be higher than the first initial program voltage.

In step S910, the program voltage of a pulse is applied so that the program operation is performed.

In step S912, the memory device 150 verifies whether or not the threshold voltage of a target memory cell reaches a target program voltage level.

When it is determined that the threshold voltage of the target memory cell does not reach the target program voltage level as result of the verification in step S912 (“N” in step S912), the memory device 150 determines whether the command is the first command or the second command in step S914.

When it is determined that the command is the first command in step S904, it may be determined that the command is the first command as well in step S914. In this case, the memory device 150 increases the program voltage by a first step voltage in step S916.

When it is determined that the command is the second command in step S904, it may be determined that the command is the second command as well in step S914. In this case, the memory device 150 increases the program voltage by a second step voltage in step S916.

In some embodiments of the present invention, the second step voltage may be higher than the first step voltage.

Until the target memory cell reaches the target program voltage level, the step S910 to the step S916 are repeatedly carried out.

When it is determined that the threshold voltage of the target memory cell reaches the target program voltage through the program operation performed in step S910 as the result of the verification in step S912 (“Y” in step S912), the current program operation is completed.

When the command is the first command, the data corresponding to the write request may be the cold data. The cold data should be stored with a high reliability because the cold data may be retained for a long duration. When the program operation is performed based on the first initial program voltage and the first step voltage, the reliability of data is improved due to increase in the charge retention of a memory cell although the program time increases.

When the command is the second command, the data corresponding to the write request may be the hot data. Since the hot data is likely to be frequently programmed, there is little concern that a number of error bits increases to such an extent that an error cannot be corrected although the reliability of the data decreases. When the program operation is performed based on the second initial program voltage and the second step voltage, a high-speed program operation may be performed even though the charge retention of the memory cell is somewhat reduced.

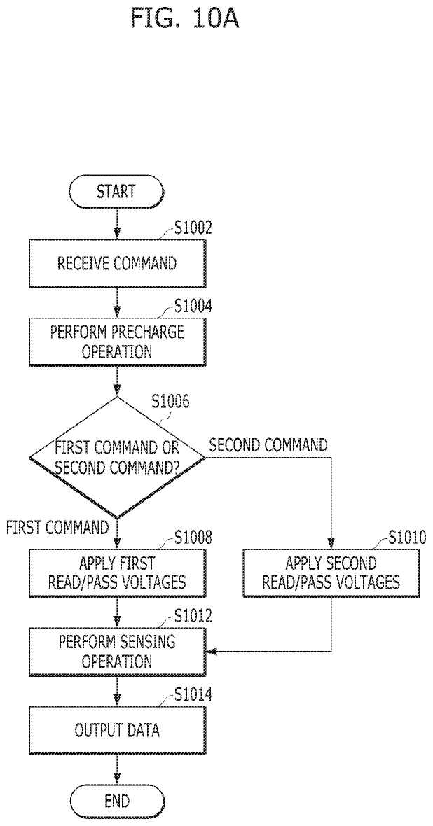

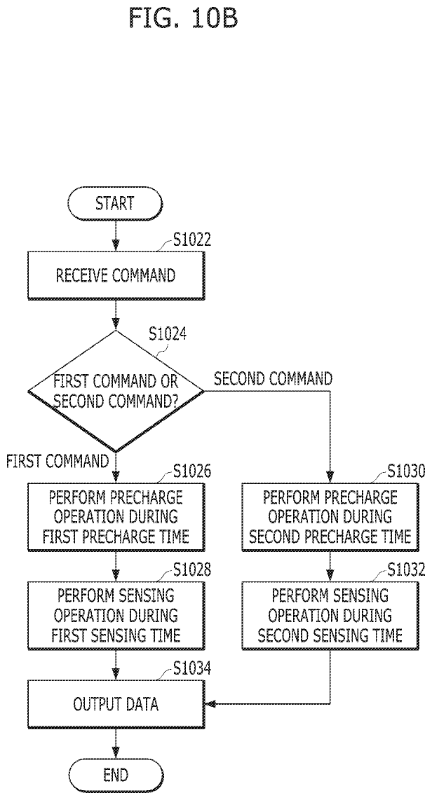

FIG. 10A is a flowchart schematically describing a read operation that the memory device 150 performs in response to a read request in accordance with an embodiment of the present invention.

In step S1002, the memory device 150 may receive the first command together with cold data from the command controller 550 and receive the second command together with hot data from the command controller 550.

The read operation may include a sensing operation. During the sensing operation, the memory device 150 applies a read voltage to a selected word line and applies a pass voltage higher than the read voltage to an unselected word line. For example, the read voltage may be approximately 0V, and the pass voltage may be approximately 5V. However, when a perpendicular electric field is generated by the pass voltage, hot carrier injection occurs in a neighboring memory cell, and a disturbance phenomenon in which a threshold voltage of the neighboring memory cell increases occurs.

When the pass voltage is lowered, an error may occur in the sensing operation but the occurrence of the disturbance phenomenon may be reduced. When the pass voltage is increased, accuracy of the sensing operation may increase but the occurrence of the disturbance phenomenon may be increased. According to a prior art, there is a problem in that either the accuracy of the sensing operation or prevention of the disturbance phenomenon has to be sacrificed irrespective of an attribute of data.

Referring to FIG. 10A, the memory device 150 according to an embodiment of the present invention performs a precharge operation on a selected bit line in step S1004.

The memory device 150 determines whether the command provided from the command controller 550 is the first command or the second command in step S1006.

When the command is the first command as a result of the determination in step S1006, the memory device 150 applies a first read voltage to a selected word line and applies a first pass voltage to an unselected word line in step S1008.

When the command is the second command as the result of the determination in step S1006, the memory device 150 applies a second read voltage to the selected word line and applies a second pass voltage to the unselected word line in step S1010.

In some embodiments of the present invention, the second pass voltage may be lower than the first pass voltage. The second read voltage may be defined according to the second pass voltage.

In some embodiments of the present invention, the second pass voltage may vary according to unselected word lines. For example, the second pass voltage which is lower than the first pass voltage may be applied to a neighboring word line among the unselected word lines, and the second pass voltage which is the same as the first pass voltage may be applied to a non-neighboring word line.

The memory device 150 performs a sensing operation to store data in a page buffer PB in step S1012.

The memory device 150 outputs the data stored in the page buffer PB to the controller 130 in step S1014, and completes the current read operation.

When the command is the first command, data read by the memory device 150 may be the cold data. Since the cold data is less likely to be frequently accessed, a read disturbance phenomenon is less likely to occur relatively in a memory cell adjacent to a memory cell in which the cold data is programmed. Accordingly, when the sensing operation is performed based on the first read voltage and the first pass voltage to increase the accuracy of the sensing operation, the reliability of data is improved.

When the command is the second command, the data read by the memory device 150 may be the hot data. Since the hot data is likely to be frequently accessed, the read disturbance phenomenon is highly likely to occur frequently in a memory cell adjacent to a memory cell in which the hot data is programmed. Accordingly, when the sensing operation is performed based on the second read voltage and the second pass voltage, the accuracy of the sensing operation is somewhat reduced but the read disturbance phenomenon is also reduced, whereby the reliability of data is improved in the long term.

FIG. 10B is a flowchart schematically describing a read operation that the memory device 150 performs in response to a read request in accordance with an embodiment of the present invention.

In step S1022, the memory device 150 may receive the first command together with cold data from the command controller 550 and receive the second command together with hot data from the command controller 550.

The read operation may include a precharge operation, a sensing operation, and an output operation. During the precharge operation, the memory device 150 may charge a bit line. During the sensing operation, the memory device 150 may apply a read voltage to a selected word line and apply a pass voltage to an unselected word line. A charge in the bit line may be reflected in a page buffer PB based on data stored in the memory cells MC0 to MCn-1.

When a precharge operation time and a sensing operation time are lengthened, a total read operation time is lengthened but the charging and discharging are sufficiently performed and reliability of the data increases. On the other hand, when the precharge operation time and the sensing operation time are shortened, the reliability of the data is somewhat reduced but the total read operation time is shortened. According to a prior art, there is a problem in that either the reliability of the data or the read operation time has to be sacrificed irrespective of an attribute of the data.

Referring to FIG. 10B, the memory device 150 according to an embodiment of the present invention determines whether the command provided from the command controller 550 is the first command or the second command in step S1024.

When the command is the first command as a result of the determination in step S1024, the memory device 150 performs the precharge operation during a first precharge time in step S1026, and then performs the sensing operation during a first sensing time in step S1028.

When the command is the second command as the result of the determination in step S1024, the memory device 150 performs the precharge operation during a second precharge time in step S1030, and then performs the sensing operation during a second sensing time in step S1032.

In some embodiments of the present invention, the second precharge time may be shorter than the first precharge time.

In some embodiments of the present invention, the second sensing time may be shorter than the first sensing time.

The memory device 150 outputs the data stored in the page buffer PB through the sensing operation in step S1034, and completes the current read operation.

When the command is the first command, data read by the memory device 150 may be the cold data. Since the cold data is less likely to be frequently accessed, an influence on overall performance is small although the read operation time is long. Accordingly, when the precharge operation is performed during the first precharge time and the sensing operation is performed during the first sensing time, the overall performance is maintained and the reliability of the data is improved.

When the command is the second command, the data read by the memory device 150 may be the hot data. When the read operation time is shortened since the hot data is more likely to be frequently accessed, the overall performance may be greatly improved. Accordingly, when the precharge operation is performed during the second precharge time and the sensing operation is performed during the second sensing time, the overall performance is greatly improved.

According to embodiments of the present invention, as the memory device 150 operates based on a request of the host 102 and a command optimized for an attribute of data corresponding to the request, performance and reliability of the memory system 110 may be improved.

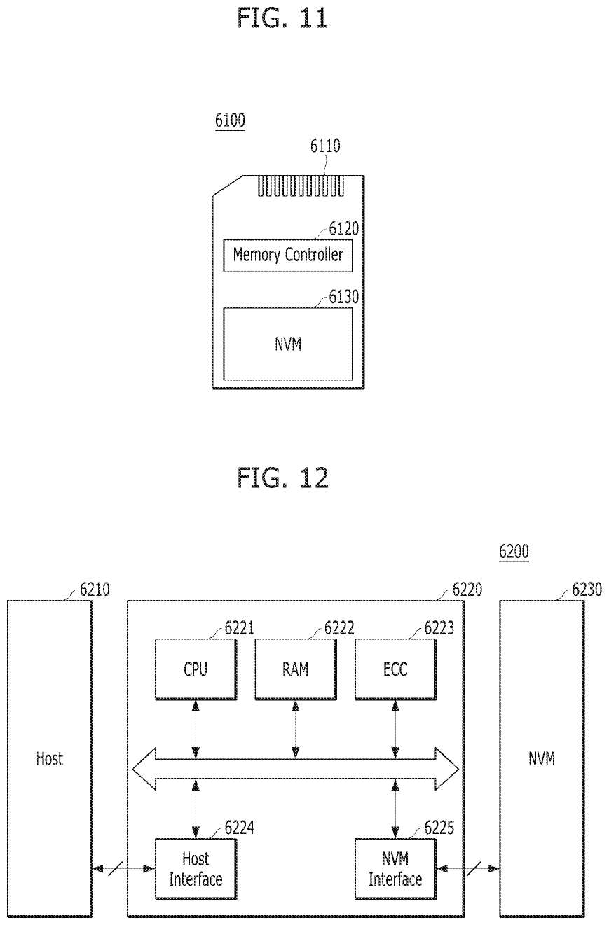

A data processing system and electronic devices to which the memory system 110 including the memory device 150 and the controller 130, which are described above with reference to FIGS. 1 to 10B, are described in detail below with reference to FIGS. 11 to 19, in accordance with an embodiment of the present invention.

FIG. 11 is a diagram schematically illustrating an example of the data processing system including the memory system in accordance with the present embodiment. Specifically, FIG. 11 schematically illustrates a memory card system to which the memory system in accordance with the present embodiment is applied.

Referring to FIG. 11, the memory card system 6100 may include a memory controller 6120, a memory device 6130 and a connector 6110.

More specifically, the memory controller 6120 may be connected to the memory device 6130, embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIG. 1, and the memory device 6130 may correspond to the memory device 150 of the memory system 110 described with reference to FIG. 1.

Thus, the memory controller 6120 may include a RAM, a processor, a host interface, a memory interface and an error correction component.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM).

The memory controller 6120 and the memory device 6130 may be integrated into a single semiconductor device. For example, the memory controller 6120 and the memory device 6130 may construct a solid-state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 12 is a diagram schematically illustrating another example of the data processing system including the memory system in accordance with the present embodiment.

Referring to FIG. 12, the data processing system 6200 may include a memory device 6230 having one or more nonvolatile memories and a memory controller 6220 for controlling the memory device 6230. The data processing system 6200 illustrated in FIG. 12 may serve as a storage medium such as a memory card (CF, SD, micro-SD or the like) or USB device, as described with reference to FIG. The memory device 6230 may correspond to the memory device 150 in the memory system 110 illustrated in FIG. 1, and the memory controller 6220 may correspond to the controller 130 in the memory system 110 illustrated in FIG. 1.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE), The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with the present embodiment may be applied to wired/wireless electronic devices or particularly a mobile electronic device.

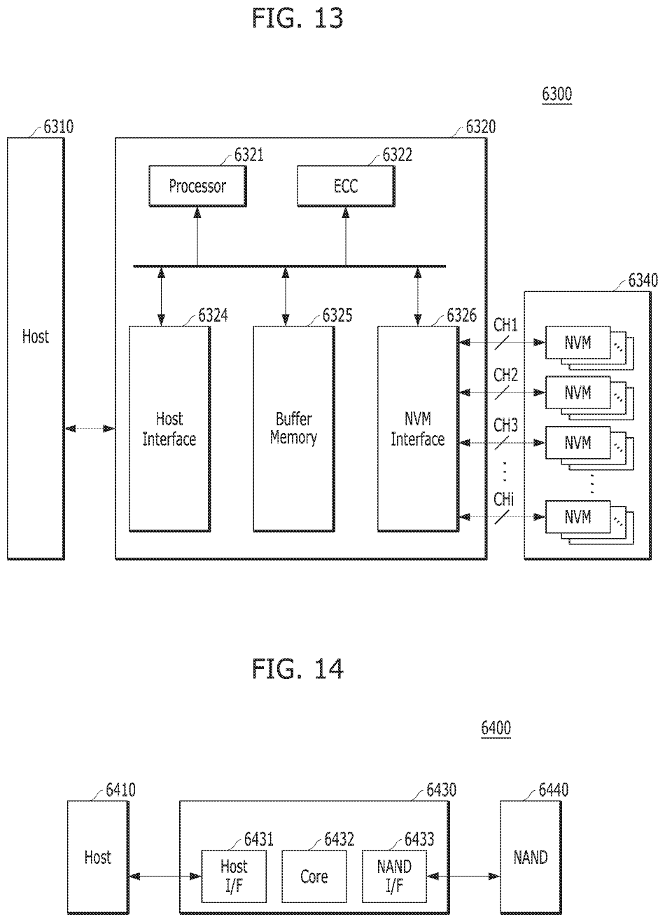

FIG. 13 is a diagram schematically illustrating another example of the data processing system including the memory system in accordance with the present embodiment. Specifically, FIG. 13 schematically illustrates an SSD to which the memory system in accordance with the present embodiment is applied.

Referring to FIG. 13, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system of FIG. 1

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 8 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 14 is a diagram schematically illustrating another example of the data processing system including the memory system in accordance with the present embodiment. Specifically, FIG. 14 schematically illustrates an embedded Multi-Media Card (eMMC) to which the memory system in accordance with the present embodiment is applied.

Referring to FIG. 14 the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

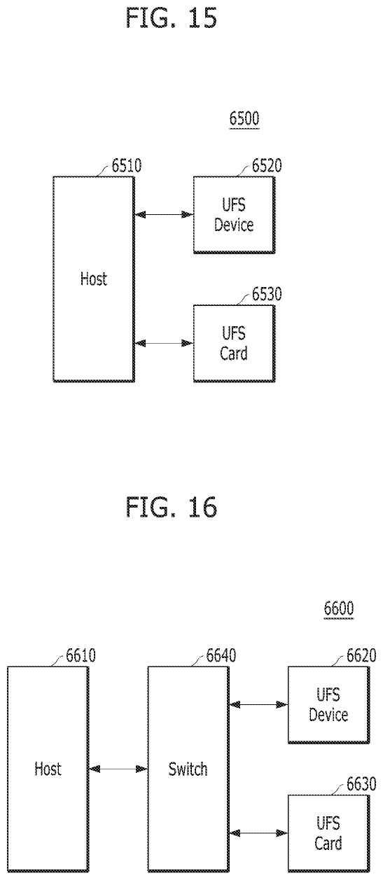

FIGS. 15 to 18 are diagrams schematically illustrating other examples of the data processing system including the memory system in accordance with the present embodiment, Specifically, FIGS. 14 to 17 schematically illustrate universal flash storage (UFS) systems to which the memory system in accordance with the present embodiment is applied.

Referring to FIGS. 15 to 18, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices including mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIG. 1. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 12 to 14, and the UFS cards 6530, 6630, 6730 and 6830 may be embodied in the form of the memory card system 6100 described with reference to FIG. 11.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 15, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. The UFS device 6520 and the UFS card 6530 may communicate with each other through link layer switching at the UniPro of the host 6510. In the present embodiment, the configuration in which one UFS device 6520 and one UFS card 6530 are connected to the host 6510 is described by way of example. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 16, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 is described by way of example. However, a plurality of UFS devices and UFS cards may be connected in parallel or in the form of a star to the switching module 6640, and a plurality of UFS cards may be connected in series or in the form of a chain to the UFS device 6620.

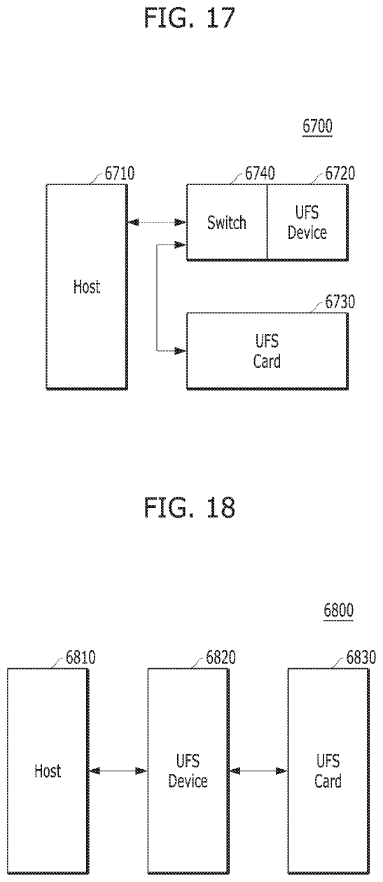

In the UFS system 6700 illustrated in FIG. 17, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. The UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 is described by way of example. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 18, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. The host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 is described by way of example. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

FIG. 18 is a diagram schematically illustrating another example of the data processing system including the memory system in accordance with an embodiment of the present invention, and more particularly illustrating a user system to which the memory system in accordance with the present embodiment is applied.

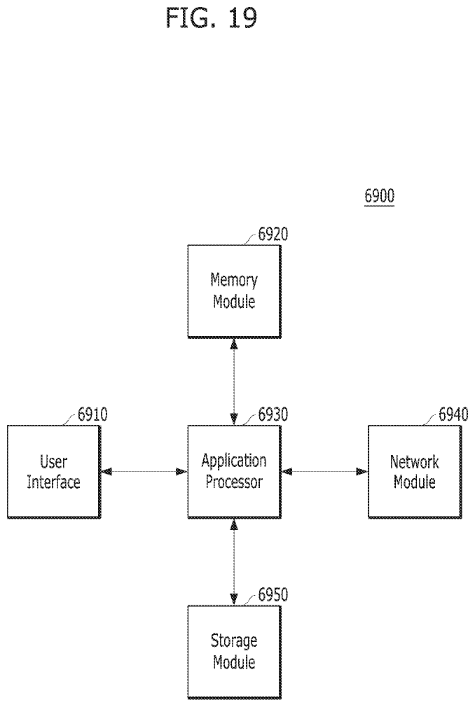

Referring to FIG. 19, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices including mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data provided from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIG. 1. Furthermore, the storage module 6950 may be embodied as an SSD, eMMC and UFS as described above with reference to FIGS. 13 to 18.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIG. 1 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

While the present invention has been described with respect to specific embodiments, it will be apparent to those skilled in the art that various changes and modifications may be made without departing from the spirit and scope of the invention as defined in the following claims.

What is claimed is:

1. A controller that controls a memory device, comprising:
a temporary storage suitable for storing a request provided from a host;
a command generator suitable for generating any one of a first command and a second command corresponding to the request based on an attribute of data corresponding to the request; and
a command controller suitable for providing the generated command to the memory device.

2. The controller of claim 1,
wherein the first command is a one-shot read command,
wherein the second command is a partial page read command, and
wherein when the request is a read request, the command generator generates the first command when the data is sequential data, and generates the second command when the data is random data.

3. The controller of claim 1,
wherein the first command is a read command performed based on a first pass voltage,
wherein the second command is a read command performed based on a second pass voltage that is lower than the first pass voltage, and
wherein when the request is a read request, the command generator generates the first command when the data is cold data, and generates the second command when the data is hot data.

4. The controller of claim 1,
wherein the first command is a read command performed based on a first read time,
wherein the second command is a read command performed based on a second read time that is shorter than the first read time, and
wherein when the request is a read request, the command generator generates the first command when the data is cold data, and generates the second command when the data is hot data.

5. The controller of claim 4, wherein the read time is at least one of a precharge time and a sensing time.

6. The controller of claim 1,
wherein the first command is a program command including a dummy pulse applying operation,
wherein the second command is a program command excluding the dummy pulse applying operation, and
wherein when the request is a program request, the command generator generates the first command when the data is random data or last data of sequential data, and generates the second command when the data is initial and intermediate data of sequential data.

7. The controller of claim 1,
wherein the first command is a program command having a first voltage,
wherein the second command is a program command having a second voltage that is higher than the first voltage, and
wherein when the request is a program request, the command generator generates the first command when the data is cold data, and generates the second command when the data is hot data.

8. The controller of claim 7, wherein the voltage is at least one of an initial program voltage and a step voltage.

9. An operating method of a memory system, comprising:
storing a request provided from a host;
generating any one of a first command and a second command corresponding to the request based on an attribute of data corresponding to the request;
providing the generated command to a memory device; and
performing, by the memory device, an operation corresponding to the command.

10. The operating method of claim 9,
wherein the first command is a one-shot read command,
wherein the second command is a partial page read command, and
wherein when the request is a read request, the generating of any one of the first command and the second command corresponding to the request includes generating the first command when the data is sequential data and generating the second command when the data is random data.

11. The operating method of claim 9,
wherein the first command is a read command performed based on a first pass voltage,
wherein the second command is a read command performed based on a second pass voltage that is lower than the first pass voltage, and
wherein when the request is a read request, the generating of any one of the first command and the second command corresponding to the request includes generating the first command when the data is cold data and generating the second command when the data is hot data.

12. The operating method of claim 9,
wherein the first command is a read command performed based on a first read time,
wherein the second command is a read command performed based on a second read time that is shorter than the first read time, and
wherein when the request is a read request, the generating of any one of the first command and the second command corresponding to the request includes generating the first command when the data is cold data and generating the second command when the data is hot data.

13. The operating method of claim 12, wherein the read time is at least one of a precharge time and a sensing time.

14. The operating method of claim 9,
wherein the first command is a program command including a dummy pulse applying operation,
wherein the second command is a program command excluding the dummy pulse applying operation, and
wherein when the request is a program request, the generating of any one of the first command and the second command corresponding to the request includes generating the first command when the data is random data or last data of sequential data, and generating the second command when the data is initial and intermediate data of sequential data.

15. The operating method of claim 9,
wherein the first command is a program command having a first voltage,
wherein the second command is a program command having a second voltage that is higher than the first voltage, and
wherein when the request is a program request, the generating of any one of the first command and the second command corresponding to the request includes generating the first command when the data is cold data and generating the second command when the data is hot data.

16. The operating method of claim 15, wherein the voltage is at least one of an initial program voltage and a step voltage.

17. A memory system comprising:
a controller including:
a temporary storage suitable for storing a request provided from a host;
a command generator suitable for generating any one of a first command and a second command corresponding to the request based on an attribute of data corresponding to the request;
a command controller suitable for providing the generated command to the memory device; and
a memory device suitable for performing an operation corresponding to the command.

18. The memory system of claim 17,
wherein the first command is a one-shot read command,
wherein the second command is a partial page read command, and
wherein when the request is a read request, the command generator generates the first command when the data is sequential data, and generates the second command when the data is random data.

19. The memory system of claim 17,
wherein the first command is a program command including a dummy pulse applying operation,
wherein the second command is a program command excluding the dummy pulse applying operation, and
wherein when the request is a program request, the command generator generates the first command when the data is random data or last sequential data of a data sequence, and generates the second command when the data is initial and medium sequential data of the data sequence.

20. The memory system of claim 17,
wherein the first command is a program command having a first voltage,
wherein the second command is a program command having a second voltage that is higher than the first voltage, and
wherein when the request is a program request, the command generator generates the first command when the data is cold data, and generates the second command when the data is hot data.
